(19) United States
(12) Patent Application Publication
(10) Pub. No.: US 2008/0136498 A1
(43) Pub. Date: Jun. 12, 2008

(54) Method and System for Buffering A Clock Signal

(76) Inventors: Razieh Roufoogaran, Venice, CA (US); Qiang Li, Irvine, CA (US); Bojko Marholev, Irvine, CA (US)

Correspondence Address: MCANDREWS HELD & MALLOY, LTD, 500 WEST MADISON STREET, SUITE 3400, CHICAGO, IL, 60661, US

(21) Appl. No.: 11/618,863

(22) Filed: Dec. 31, 2006

Related U.S. Application Data
(60) Provisional application No. 60/868,818, filed on Dec. 6, 2006.

(51) Int. Cl. H03K 3/01

(52) U.S. Cl. 327/534

(57) ABSTRACT

A method and system for buffering a clock signal is provided. The method may include self-biasing a PMOS transistor of a buffer, utilized for amplifying an in-phase/quadrature phase signal, to produce a first bias voltage at the gate of a PMOS transistor, and biasing an NMOS transistor of the buffer via a controllable current source to produce a second bias voltage at the gate of the NMOS transistor. The gain of the buffer may be controlled by varying a controllable current source coupled to a second NMOS transistor configured as a diode. Two coupling capacitors may be utilized to remove a DC component of the signal. Multiple buffers may be coupled end-to-end to increase the overall drive capability, where the channel width of the transistors within the transistors may be doubled in each successive buffer.

### CROSS-REFERENCE TO RELATED APPLICATIONS/INCORPORATION BY REFERENCE

This application makes reference to, claims priority to, and claims the benefit of U.S. Provisional Application Ser. No. 60/868,818, filed on Dec. 6, 2006.

This application makes reference to:

U.S. application Ser. No. ______ (Attorney Docket No. 18122US02) filed on even date herewith;
U.S. application Ser. No. ______ (Attorney Docket No. 18144US02) filed on even date herewith;
U.S. application Ser. No. ______ (Attorney Docket No. 18145US02) filed on even date herewith;
U.S. application Ser. No. ______ (Attorney Docket No. 18147US02) filed on even date herewith.

Each of the above stated applications is hereby incorporated herein by reference in its entirety.

### FIELD OF THE INVENTION

Certain embodiments of the invention relate to mobile communication systems. More specifically, certain embodiments of the invention relate to a method and system for buffering a clock signal.

### BACKGROUND OF THE INVENTION

The development and design of radio receivers, transmitter, and/or transceiver systems has been driven by the great demand for devices for mobile wireless communication applications, especially handset devices. With the ever decreasing size of mobile handsets and an ever increasing demand for voice, data, and/or video processing capabilities, there is an growing need to develop radio receivers and transmitters that not only meet these challenging performance requirements, but that do so in smaller integrated circuit (IC) footprints, that is, at lower cost, and with greater power efficiency. One approach that aims at addressing these demands is the development of highly integrated receivers, transmitters, and/or transceivers in complementary metal oxide semiconductor (CMOS) technology to minimize the number of off-chip components.

As a result of these highly integrated systems, radio receivers, transmitters, and/or transceivers may comprise a large number of components and/or circuits, which may be utilized for the processing of signals. The design of optimal systems may require that these components and/or circuits operate within certain requirements or constraints for a wide range of operational conditions. For example, power amplifiers (PA) and/or low noise amplifiers (LNA) may be required to operate at an optimal gain level. However, this gain level may vary significantly based on operational conditions, such as temperature and/or voltage supplies, or based on manufacturing conditions, such as the non-uniformity in transistor parameters that result from normal variations in the manufacturing process. These variations generally referred to as process, voltage, and temperature (PVT) variations, may have a significant effect in the overall performance of wireless handsets.

In systems based on the global system for mobile communications (GSM) standard, for example, PVT variations in many of the circuits and/or components utilized in the receiver or the transmitter may produce errors in the generation of “I” (in-phase) and “Q” (quadrature) signal components. These errors may result in a significant degradation in the signal-to-noise ratio (SNR) and/or the bit-error-rate (BER) performance of GSM handsets.

In-phase (I) and quadrature (Q) signals are typically utilized in modulation and demodulation sections of transceivers in cellular handsets and other types of communication devices. The I and Q signals, which are 90 degrees out of phase, may be generated, for example, by coupling an input local oscillator signal to first and second outputs via different RC networks. For example, one RC network may include a capacitor coupled between the input and the first output and a resistor coupled between the first output and ground and the other RC network may include a capacitor coupled between the input and the second output and a resistor coupled between the second output and ground. Various buffers may be utilized to couple the various RC networks. To achieve balanced I and Q signals or I and Q signals having the same amplitude, the resistors in each RC network and the capacitors in each RC network must have the same and predetermined value according to the operation frequency. In addition, it may be necessary to match the gains of the various buffers. However, power supply variations may affect the gain the buffers. This in turn may result in an imbalance between the gains in, for example, the I and Q signals. For example, the gain in the I path may be different from the gain in the Q path.

One method for dealing with this issue may be to increase the amount of headroom in the power supply to guarantee an adequate power supply. However, this may result in inefficient use of power and may, for example lead to poor battery life in a mobile device.

Further limitations and disadvantages of conventional and traditional approaches will become apparent to one of skill in the art, through comparison of such systems with some aspects of the present invention as set forth in the remainder of the present application with reference to the drawings.

### BRIEF SUMMARY OF THE INVENTION

A system and/or method is provided for buffering a clock signal substantially as shown in and/or described in connection with at least one of the figures, as set forth more completely in the claims.

These and other advantages, aspects and novel features of the present invention, as well as details of an illustrated embodiment thereof, will be more fully understood from the following description and drawings.

### BRIEF DESCRIPTION OF SEVERAL VIEWS OF THE DRAWINGS

FIG. 1 is a block diagram of exemplary communication between several devices, which may be utilized in connection with an embodiment of the invention.

FIG. 2 is a block diagram that illustrates an exemplary single radio chip that supports WLAN and Bluetooth radio operations, in accordance with an embodiment of the invention.

FIG. 3 is a block diagram of an exemplary local oscillator generator architecture for multi-standard wireless communication systems, in accordance with an embodiment of the invention.

FIG. 4 is a circuit diagram of an exemplary single stage clock buffer circuit, in accordance with an embodiment of the invention.

FIG. 5 is a circuit diagram of an exemplary multistage clock buffer circuit for driving a capacitive load in the presence of supply voltage variation, in accordance with an embodiment of the invention.

FIG. 6A is a circuit diagram of a voltage regulator circuit for a clock buffer, in accordance with an embodiment of the invention.

FIG. 6B is a circuit diagram of an exemplary multistage clock buffer circuit for driving a capacitive load, in accordance with an embodiment of the invention.

### DETAILED DESCRIPTION OF THE INVENTION

Certain embodiments of the invention may be found in a method and system for buffering a clock signal. The method may include self-biasing a PMOS transistor of a buffer, utilized for amplifying an in-phase/quadrature phase signal, to produce a first bias voltage at the gate of a PMOS transistor, and biasing an NMOS transistor of the buffer via a controllable current source to produce a second bias voltage at the gate of the NMOS transistor. The gain of the buffer may be controlled by varying a controllable current source coupled to a second NMOS transistor configured as a diode. Two coupling capacitors may be utilized to remove a DC component of the signal. Multiple buffers may be coupled end-to-end to increase the overall drive capability, where the channel width of the transistors within the transistors may be doubled in each successive buffer.

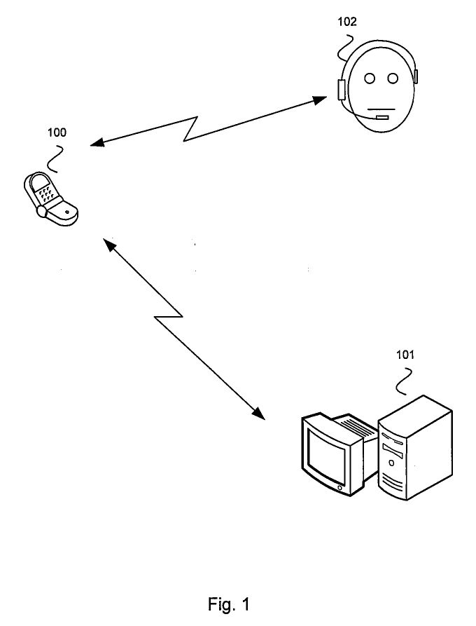

FIG. 1 is a block diagram of exemplary communication between several devices, which may be utilized in connection with an embodiment of the invention. Referring to FIG. 1, there is shown a mobile device 100, a computer 101, and a headset 102. The mobile device 100, computer 101 and headset 102, may comprise suitable logic, circuitry and/or code that may enable establishment of a Bluetooth, WLAN, or GSM connection. In this regard, the mobile device may establish a Bluetooth link with the headset. In this case, the mobile device may be the master and the headset may be the slave. The communication between the mobile device 100 and the headset 102 may comprise voice information and may utilize two timeslots, where one timeslot may be utilized for uplink communication and the other may be utilized for downlink communication. The mobile device 100 may also establish a WLAN connection with the computer 101. The communication between the mobile device 100 and the computer 101 may comprise data communication. For example, a user may wish to synchronize an address book on the computer 101 with the address book in the mobile device 100.

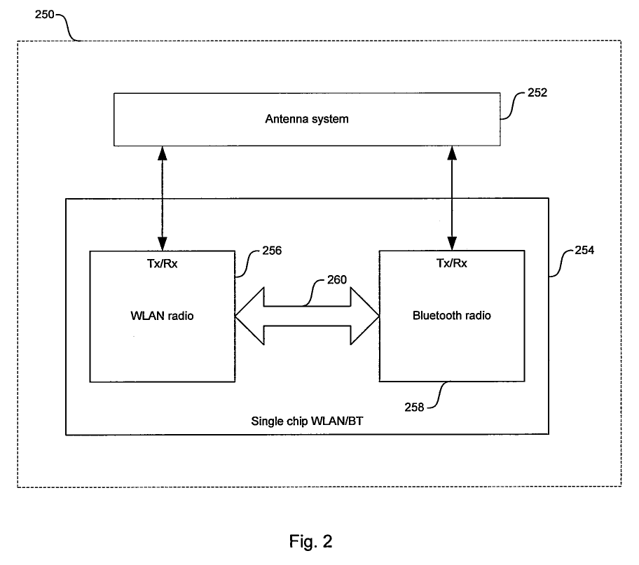

FIG. 2 is a block diagram that illustrates an exemplary single radio chip that supports WLAN and Bluetooth radio operations, in accordance with an embodiment of the invention. Referring to FIG. 2, there is shown a mobile phone 250 that may comprise a WLAN/Bluetooth coexistence antenna system 252 and a single chip WLAN/Bluetooth (WLAN/BT) radio device 254. The single chip WLAN/BT radio device 254 may comprise a WLAN radio portion 256 and a Bluetooth radio portion 258. The single chip WLAN/BT radio device 254 may be implemented based on a system-on-chip (SOC) architecture, for example.

The WLAN/Bluetooth coexistence antenna system 252 may comprise suitable hardware, logic, and/or circuitry that may be enabled to provide WLAN and Bluetooth communication between external devices and a coexistence terminal. The WLAN/Bluetooth coexistence antenna system 252 may comprise at least one antenna for the transmission and reception of WLAN and Bluetooth packet traffic. In a single antenna system, the antenna system 252 may comprise, for example, a transmit/receive switch, which may be utilized to couple the single antenna to the WLAN radio portion 256 and the Bluetooth radio portion 258.

The WLAN radio portion 256 may comprise suitable logic, circuitry, and/or code that may be enabled to process WLAN protocol packets for communication. The WLAN radio portion 256 may be enabled to transfer and/or receive WLAN protocol packets and/or information to the WLAN/Bluetooth coexistence antenna system 252 via a single transmit/receive (Tx/Rx) port. In some instances, the transmit port (Tx) may be implemented separately from the receive port (Rx). The WLAN radio portion 256 may also be enabled to generate signals that control at least a portion of the operation of the WLAN/Bluetooth coexistence antenna system 252. Firmware operating in the WLAN radio portion 256 may be utilized to schedule and/or control WLAN packet communication, for example.

The WLAN radio portion 256 may also be enabled to receive and/or transmit priority signals 260. The priority signals 260 may be utilized to schedule and/or control the collaborative operation of the WLAN radio portion 256 and the Bluetooth radio portion 258. In this regard, the priority signals 260 may comprise a plurality of signals to implement various levels of transmission priority. For example, a single signal implementation may result in two transmission priority levels, a two-signal implementation may result in up to four different transmission priority levels, and a three-signal implementation may result in up to eight different transmission priority levels.

The Bluetooth radio portion 258 may comprise suitable logic, circuitry, and/or code that may be enabled to process Bluetooth protocol packets for communication. The Bluetooth radio portion 258 may be enabled to transfer and/or receive Bluetooth protocol packets and/or information to the WLAN/Bluetooth coexistence antenna system 252 via a single transmit/receive (Tx/Rx) port. In some instances, the transmit port (Tx) may be implemented separately from the receive port (Rx). The Bluetooth radio portion 258 may also be enabled to generate signals that control at least a portion of the operation of the WLAN/Bluetooth coexistence antenna system 252. Firmware operating in the Bluetooth radio portion 258 may be utilized to schedule and/or control Bluetooth packet communication. The Bluetooth radio portion 258 may also be enabled to receive and/or transmit priority signals 260. A portion of the operations supported by the WLAN radio portion 256 and a portion of the operations supported by the Bluetooth radio portion 258 may be performed by common logic, circuitry, and/or code.

In some instances, at least a portion of either the WLAN radio portion 256 or the Bluetooth radio portion 258 may be disabled and the wireless terminal may operate in a single-communication mode, that is, coexistence may be disabled. When at least a portion of the WLAN radio portion 256 is disabled, the WLAN/Bluetooth coexistence antenna system 252 may utilize a default configuration to support Bluetooth communication. When at least a portion of the Bluetooth radio portion 258 is disabled, the WLAN/Bluetooth coexistence antenna system 252 may utilize a default configuration to support WLAN communication.

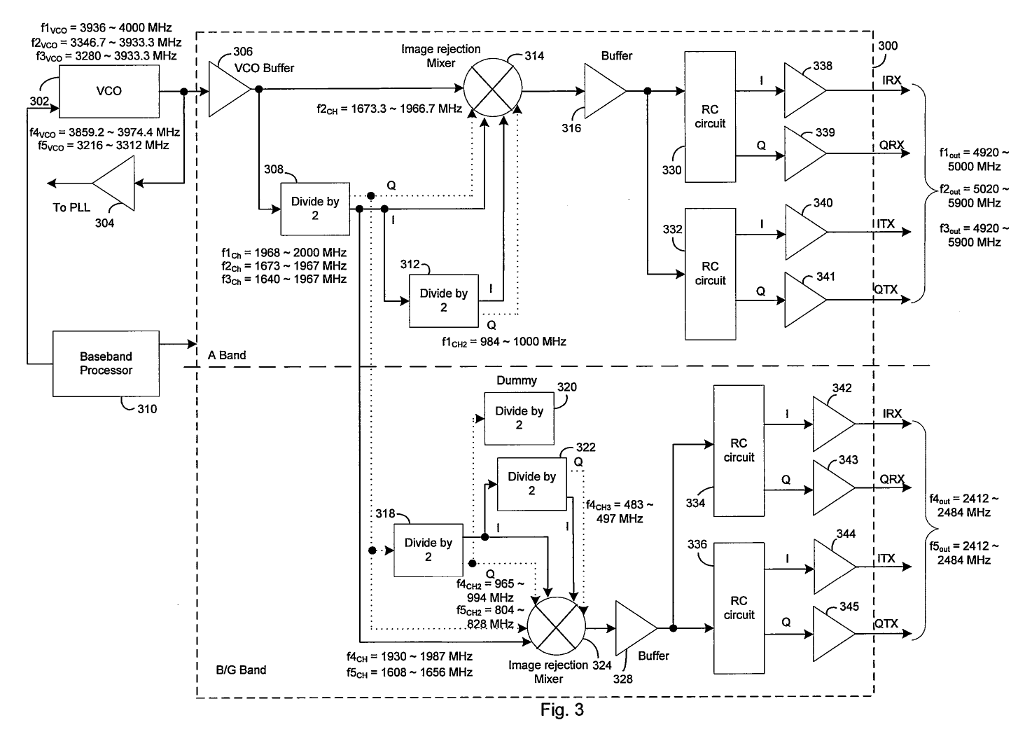

FIG. 3 is a block diagram of an exemplary local oscillator generator architecture for multi-standard wireless communication systems, in accordance with an embodiment of the invention. Referring to FIG. 3, there is shown a VCO 302, a buffer 304, a processor 310, and a LO generator 300. The LO generator 300 may comprise a VCO buffer 306, a plurality of image rejection mixers 314 and 324, a plurality of divide by 2 circuits 308, 312, 318, 320, and 322, a plurality of buffers 316 and 328, a plurality of RC circuits 330, 332, 334, and 336, and a plurality of last stage buffers 338, 339, 340, 341, 342, 343, 344, and 345.

The VCO 302 may comprise suitable logic, circuitry, and/or code that may be enabled to generate an output frequency that may be a multiple of the frequency of a reference oscillator. The VCO 302 may be enabled to operate in a plurality of frequency ranges. For example, the VCO 302 may be enabled to operate in a first frequency range, f1_{VCO} of about 3936 MHz to 4000 MHz in divide by 4 mode to generate an output frequency range f1ₒᵤₜ of about 4920 MHz to 5000 MHz, where f1ₒᵤₜ=f1_{VCO}× 5/4, for example, a second frequency range, f2_{VCO} of about 3346.7 MHz to 3933.3 MHz in divide by 2 mode to generate an output frequency range f2ₒᵤₜ of about 5020 MHz to 5900 MHz, where f2ₒᵤₜ=f2_{VCO}× 3/2, for example, and a third frequency range, f3_{VCO} of about 3280 MHz to 3933.3 MHz in divide by 2 mode to generate an output frequency range f3ₒᵤₜ of about 4920 MHz to 5900 MHz, where f3ₒᵤₜ=f3_{VCO}× 3/2, for example, for 802.11a band WLAN operation. The VCO 302 may be enabled to operate in a fourth frequency range, f4_{VCO} of about 3859.2 MHz to 3974.4 MHz in divide by 8 mode to generate an output frequency range f4ₒᵤₜ of about 2412 MHz to 2484 MHz, where f4ₒᵤₜ=f4_{VCO}×⅝, for example, and a fifth frequency range, f5_{VCO} of about 3216 MHz to 3312 MHz in divide by 4 mode to generate an output frequency range f5ₒᵤₜ of about 2412 MHz to 2484 MHz, where f5ₒᵤₜ=f5_{VCO}×¾, for example, for 802.11b/g band WLAN operation. The buffer 304 may be enabled to receive a signal from the VCO 302 and generate an output to a PLL in the same frequency range as VCO 302.

The baseband processor 310 may comprise suitable logic, circuitry, and/or code that may be enabled to select LO generator 300 divider configurations depending on a required output frequency range and an input frequency range of operation at VCO 302 based on a particular wireless band of operation, for example, 802.11a/b/g wireless band of operation. The VCO buffer 306 may comprise suitable logic, circuitry, and/or code that may be enabled to buffer and/or store the received signals from the VCO 302. The plurality of divide by 2 circuits 308, 312, 318, 320, and 322 may comprise suitable logic, circuitry, and/or code that may be enabled to generate the in-phase (I) and quadrature (Q) components of a received signal, and may output the generated I and Q components to a plurality of mixers.

The divide by 2 circuit 308 may be enabled to divide the frequency of the received input signal from the VCO 302 and generate an output signal with half the frequency of the received input signal. For example, the divide by 2 circuit 308 may generate I and Q components of an output signal in the frequency range, f1_{CH} of about 1968 MHz to 2000 MHz, for example, for 802.11a band WLAN operation in divide by 4 mode and VCO range of f1_{VCO}. The divide by 2 circuit 308 may generate I and Q components of an output signal in the frequency range, f2_{CH} of about 1673 MHz to 1967 MHz, for example, for 802.11a band WLAN operation in divide by 2 mode and VCO range of f2_{VCO}. The divide by 2 circuit 308 may generate I and Q components of an output signal in the frequency range, f3_{CH} of about 1640 MHz to 1967 MHz, for example, for 802.11a band WLAN operation in divide by 2 mode and VCO range of f3_{VCO}. The divide by 2 circuit 308 may generate I and Q components of an output signal in the frequency range, f4_{CH} of about 1930 MHz to 1987 MHz, for example, for 802.11b/g band WLAN operation in divide by 8 mode and VCO range of f4_{VCO}. The divide by 2 circuit 308 may generate I and Q components of an output signal in the frequency range, f5_{CH} of about 1608 MHz to 1656 MHz, for example, for 802.11b/g band WLAN operation in divide by 4 mode and VCO range of f5_{VCO}.

The divide by 2 circuit 312 may be enabled to divide the frequency of the received I component of the output signal from the divide by 2 circuit 308 and generate an output signal with half the frequency of the received input signal. For example, the divide by 2 circuit 312 may generate I and Q components of an output signal in the frequency range, f1_{CH2} of about 984 MHz to 1000 MHz, for example, for 802.11a band WLAN operation in divide by 4 mode and VCO range of f1_{VCO}.

The divide by 2 circuit 318 may be enabled to divide the frequency of the received Q component of the output signal from the divide by 2 circuit 308 and generate an output signal with half the frequency of the received input signal for 802.11b/g band WLAN operation. The divide by 2 circuit 318 may generate I and Q components of an output signal in the frequency range, f4_{CH2} of about 965 MHz to 994 MHz, for example, in divide by 8 mode and VCO range of f4_{VCO}. The divide by 2 circuit 318 may generate I and Q components of an output signal in the frequency range, f5_{CH2} of about 804 MHz to 828 MHz, for example, in divide by 4 mode and VCO range of f5_{VCO}. The divide by 2 circuit 322 may be enabled to divide the frequency of the received I component of the output signal from the divide by 2 circuit 318 and generate an output signal with half the frequency of the received input signal for 802.11b/g band WLAN operation. For example, the divide by 2 circuit 322 may generate I and Q components of an output signal in the frequency range, f4_{CH3} of about 482 MHz to 497 MHz, for example for 802.11b/g band WLAN operation in divide by 8 mode and VCO range of f4_{VCO}.

The divide by 2 circuit 320 may be a dummy circuit and may be enabled to receive the Q component of the output signal from the divide by 2 circuit 318. The Q component generated by the divide-by-two circuit 318 may be coupled to the dummy load or divide by 2 circuit 320 with negligible power consumption. This results in symmetric loading of the divide-by-two circuit 318 and perfect I-Q matching. The dummy load may comprise a load that is equivalent to the divide by 2 circuit 322.

The divide by 2 circuit 308 may be symmetrically loaded. For example, the I component of the divide by 2 circuit 308 may be coupled to a divide by 2 circuit 312 and the plurality of image rejection mixers 314 and 324. Similarly, the Q component of the divide by 2 circuit 308 may be coupled to a divide by 2 circuit 318 and the plurality of image rejection mixers 314 and 324.

The image rejection mixer 314 may comprise suitable logic, circuitry, and/or code that may be enabled to mix the frequencies of the received signals from the VCO 302 and at least one of the plurality of divide by 2 circuits 308 and 312 to generate an output signal to the buffer 316. The image rejection mixer 314 may be enabled to suppress unwanted images of frequencies by processing the received signal and image differently. The image rejection mixer 314 may be enabled to receive the I and Q components of the output signals generated by the plurality of divide by 2 circuits 308 and 312. The image rejection mixer 314 may be enabled to generate an output signal for the particular wireless band of operation based on mixing a plurality of received signals within a selected frequency range. The buffer 316 may be enabled to generate a buffered output of the received signal from the image rejection mixer 314 to the plurality of RC circuits 330 and 332. The baseband processor 310 may be enabled to select at least one of the plurality of signals received from the plurality of divide by 2 circuits 308 and 312. For example, the image rejection mixer 314 may be enabled to mix the frequency of the received signal from the VCO buffer 306, and one of the frequencies of the I and Q components of the received signal from the divide by 2 circuit 308, and the frequency of the I and Q components of the received signal from the divide by 2 circuit 312 to generate an output signal to the buffer 316.

The image rejection mixer 324 may comprise suitable logic, circuitry, and/or code that may be enabled to mix the frequencies of the received signals from the divide by 2 circuit 308 and at least one of the plurality of divide by 2 circuits 318 and 322 to generate an output signal to the buffer 328. The image rejection mixer 324 may be enabled to suppress unwanted images of frequencies by processing the received signal and image differently. The image rejection mixer 324 may be enabled to receive the I and Q components of the output signals generated by the plurality of divide by 2 circuits 308, 318, and 322. The image rejection mixer 324 may be enabled to generate an output signal for the particular wireless band of operation based on mixing a plurality of received signals within a selected frequency range. The buffer 328 may be enabled to generate a buffered output of the received signal from the image rejection mixer 324 to the plurality of RC circuits 334 and 336. The baseband processor 310 may be enabled to select at least one of the plurality of signals received from the plurality of divide by 2 circuits 318 and 322. For example, the image rejection mixer 324 may be enabled to mix the frequency of the I and Q components of the received signal from the divide by 2 circuit 308, and one of the frequencies of the I and Q components of the received signal from the divide by 2 circuit 318 and the frequency of the I and Q components of the received signal from the divide by 2 circuit 322 to generate an output signal to the buffer 328.

The plurality of RC circuits 330 and 332 may comprise suitable logic, circuitry, and/or code that may be enabled to generate I and Q components of a received signal to the plurality of last stage buffers 338, 339, 340, and 341 by shifting the phase of the received signal from the buffer 316. The plurality of last stage buffers 338, 339, 340, and 341 may be enabled to amplify signals and generate an output to a transmitter/receiver for 802.11a band WLAN operation. The I and Q components of the output signal generated by the plurality of last stage buffers 338, 339, 340 and 341 may be in the frequency range, f1ₒᵤₜ of about 4920 MHz to 5000 MHz, for example, for 802.11a band WLAN operation in divide by 4 mode and VCO range of f1_{VCO}. The I and Q components of the output signal generated by the plurality of last stage buffers 338, 339, 340 and 341 may be in the frequency range, f2ₒᵤₜ of about 5020 MHz to 5900 MHz, for example, for 802.11a band WLAN operation in divide by 2 mode and VCO range of f2_{VCO}. The I and Q components of the output signal generated by the plurality of last stage buffers 338, 339, 340 and 341 may be in the frequency range, f3ₒᵤₜ of about 4920 MHz to 5900 MHz, for example, for 802.11a band WLAN operation in divide by 2 mode and VCO range of f3_{VCO}.

The plurality of RC circuits 334 and 336 may comprise suitable logic, circuitry, and/or code that may be enabled to generate I and Q components of a received signal to the plurality of last stage buffers 342, 343, 344, and 345 by shifting the phase of the received signal from the buffer 328. The plurality of last stage buffers 342, 343, 344, and 345 may be enabled to amplify signals and generate an output to a transmitter/receiver for 802.11b/g band WLAN operation. The I and Q components of the output signal generated by the plurality of last stage buffers 342, 343, 344 and 345 may be in the frequency range, f4ₒᵤₜ of about 2412 MHz to 2484 MHz, for example, for 802.11b/g band WLAN operation in divide by 8 mode and VCO range of f4_{VCO}. The I and Q components of the output signal generated by the plurality of last stage buffers 341, 343, 344, and 345 may be in the frequency range, f5ₒᵤₜ of about 2412 MHz to 2484 MHz, for example, for 802.11b/g band WLAN operation in divide by 4 mode and VCO range of f5_{VCO}.

In a chip handling both WLAN connection and Bluetooth connection, the baseband processor 310 may avoid pulling of the VCO 302 by the second harmonics generated by the VCO 202 by selecting an input frequency range of operation at VCO 302 based on a particular wireless band of operation, for example, 802.11a/b/g wireless band of operation. Similarly, the I and Q components of an output signal generated by the divide by 2 circuit 308 in the frequency range of about 1673.3 MHz to 1966.7 MHz, for example, may not interfere with frequencies of the generated signals of the VCO 202 operating in a Bluetooth mode of operation.

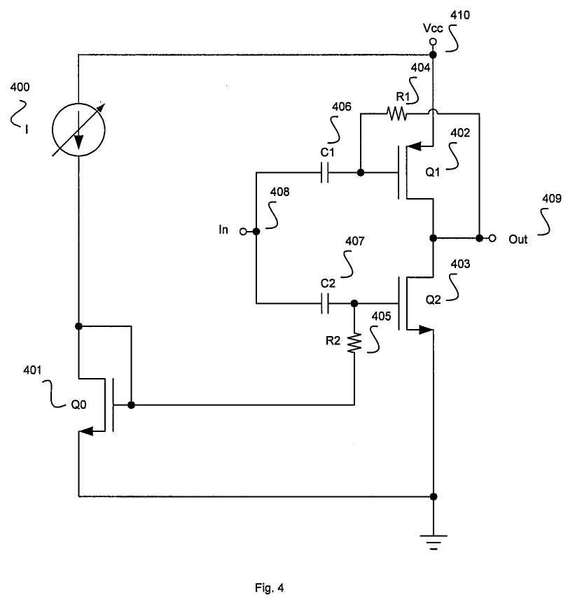

FIG. 4 is a circuit diagram of an exemplary single stage clock buffer circuit, in accordance with an embodiment of the invention. Referring to FIG. 4; there is shown an adjustable current source 400; transistors Q0 401, Q2 402, and Q3 403; resistors R1 404 and R2 405; capacitors C1 406 and C2 407; a clock input node 408; a clock output node 409; and a power supply node 410.

The adjustable current source 400 may comprise suitable circuitry that may enable the generation of a variable current supply. The output current produced by the adjustable current source 400 may be immune to variations in the voltage at the power supply node 410. Current from the adjustable current source 400 may be coupled to transistor Q0 401.

The transistor Q0 401 may be an NMOS transistor and the gate and source may be coupled. In this configuration, the transistor Q0 401 may take on characteristics of a diode when, for example, the current from the adjustable current source 400 is passed through Q0 401. A voltage drop may develop across the gate and source of Q0 401. For example, the voltage measured at the gate by virtue of the coupling, may equal 0.9 volts for a given current. The voltage measured at the gate of the Q0 401 may increase as the current flow through Q0 401 increases. Stated differently, variations in the amount of current produced by the adjustable current source 400 may produce corresponding variations in voltage across the Q0 401.

The transistor Q1 402 may be a PMOS transistor and Q2 403 may be an NMOS transistor. The gate of Q1 402 may be coupled to a first end of the resistor R1 404 and a first end of capacitor C1 406. The source of the transistor Q1 402 may be coupled to the power supply node 410. The drain of the transistor Q1 402 may be coupled to a second end of resistor R1 404, the output node 409, and the drain of transistor Q2 403. The gate of the transistor Q2 403 may be coupled to a first end of the capacitor C2 407 and a first end of the resistor R2 405. The source of the transistor Q2 403 may be coupled to ground. A second end of the capacitor C1 and the capacitor C2 may be coupled and to the clock input node 408.

The configuration of the transistors Q1 402 and Q2 403 may enable the amplification of a clock signal present at the clock input node 408. In this regard, the amount of amplification may depend on the biasing of the transistors Q1 402 and Q2 403. The DC voltage present on the respective gates may determine the bias point of the transistors. The capacitors C1 406 and C2 407 may block the DC voltages on the respective gates from interfering with one another while at the same time may allow the AC portion of the clock signal to reach the respective gates. The DC voltage present on the gate of the transistor Q2 403 may equal the voltage drop across the transistor Q0 401. R1 404 may enable the gate of the transistor Q1 402 to self bias (Diode characteristic) to a voltage equal to the difference between the voltage at the power supply node 410 and the gate voltage of the transistor Q2 403. Once biasing has been established, the gate to source voltage at the transistors Q1 402 and Q2 403 may be above ½ of the voltage at the power supply node 410.

In operation, a clock signal may be input into the clock input node 408 and amplified by the transistors Q1 402 and Q2 403. The amplified clock signal may then be output from the clock output node 409. The amount of gain produced by the transistors Q1 402 and Q2 403 may be controlled by varying the voltage at the gate of Q2 403. This voltage may be equal to the voltage drop across the transistors Q0 401, which may be controlled by varying the output current from the adjustable current source 400. Thus, the gain produced by the transistors Q1 402 and Q2 403 may be controlled via the adjustable current source 400. As stated above, the amount of current output from the adjustable current source 400 may not be susceptible to variations in the voltage at the power supply node 410. Thus, the circuit shown in FIG. 4 may enable the amplification of a clock signal with a constant gain.

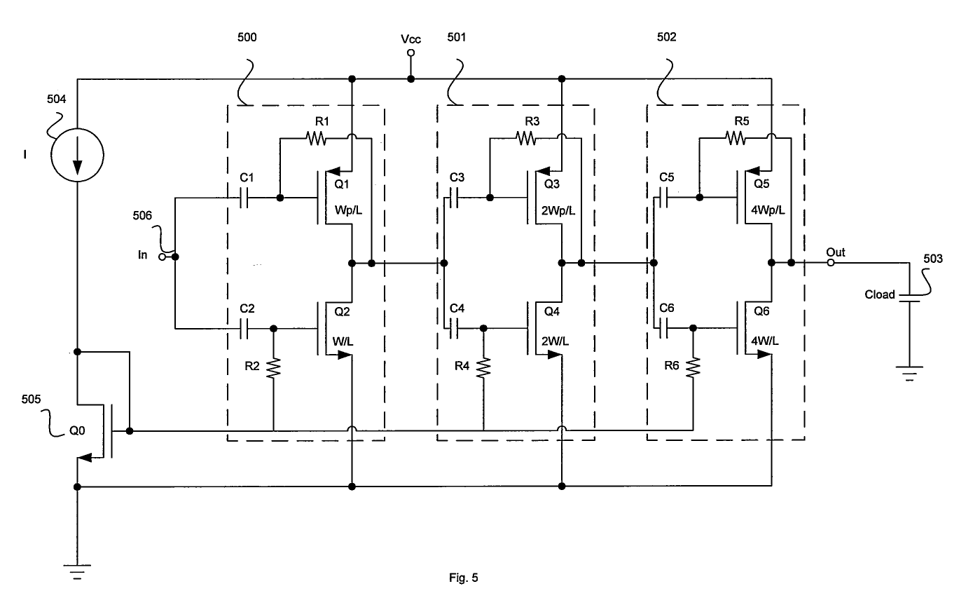

FIG. 5 is a circuit diagram of an exemplary multistage clock buffer circuit for driving a capacitive load in the presence of supply voltage variation, in accordance with an embodiment of the invention. Referring to FIG. 5, there is shown an adjustable current source 504, transistor Q0 505, three clock driver stages 500, 501, and 502, a clock input node 506, and a capacitive load 503. The circuitry shown in FIG. 5 may correspond to the plurality of last stage buffers 338, 339, 340, 341, 342, 344, 345 shown in FIG. 3 above. The adjustable current source 504 may comprise suitable circuitry that may enable the generation of a variable current supply. The transistor Q0 505 may be an NMOS transistor and the gate and source may be coupled. The adjustable current source 504 and the transistor Q0 505 may be utilized to control the gain of the three clock driver stages 500, 501, and 502 as described above in FIG. 4.

The three clock driver stages 500, 501, and 502 may comprise suitable circuitry that may enable the amplification of a clock signal. In this regard, the three clock driver stages 500, 501, and 502 may comprise the circuitry described in FIG. 4 above. The three clock driver stages 500, 501, and 502 may differ in that the transistors utilized may have different sizes. For example, the transistors in the first stage 500 may have a width equal to W and a length equal to L. The width and length may govern the driving capabilities and gain of the transistors. The transistors in the second clock driver stage 501 may have a width equal to 2W and a length equal to L. In other words, the width of the transistors may be double that of the transistors in the first stage. The transistors in the third clock driver stage 502 may have a width equal to 4W and a length equal to L. The transistors in the third clock driver stage 502 may be capable of driving a relatively large capacitive load.

In operation, a clock signal may be input into the clock input node 506 and may be applied to successive stages of amplification. The third clock driver stage 502 may then be capable of applying the amplified version of the clock signal to a relatively large capacitive load 503. As described in FIG. 4 above, the gain of the three clock driver stages 500, 501, and 502 may be controlled via the adjustable current source 504, which may not be susceptible to variations in the voltage in the power supply. Thus, the circuit shown in FIG. 5 may enable the stable amplification of a clock signal and the driving of a relatively large capacitive load 503 in the presence of supply voltage variations. It should be understood that the number of stages shown is only exemplary and that more or less stages may be utilized depending on factors such as the amount of gain required, the size of the load, and the types of transistors.

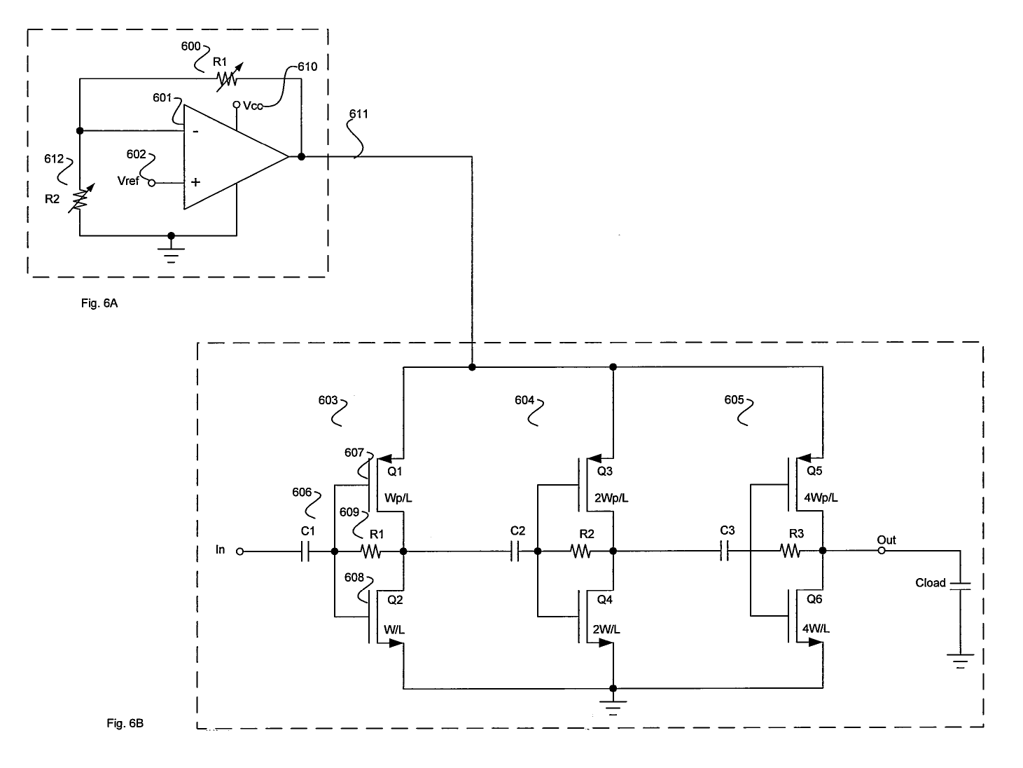

FIG. 6A is a circuit diagram of a voltage regulator circuit for a clock buffer, in accordance with an embodiment of the invention. Referring to FIG. 6A, there is shown a differential amplifier 601, resistors R1 600 and R2 612, a voltage reference input 602, a supply voltage input 610, and a regulator output 611. In operation, the voltage regulator circuit may be capable of producing a constant output voltage while the supply voltage at the supply voltage input 610 varies. The output of the voltage regulator may be calculated by the formula:

$$Vout = Vref ( 1 + \frac{R 1}{R 2} )$$

where Vout is the regulator output 611 and Vref is the voltage at the voltage reference input 602. The voltage Vref may, for example, be generated utilizing a bandgap voltage reference device. In this regard, the bandgap voltage reference device may be capable of providing a steady voltage, such as 1.2 to 1.8 volts, over a wide range of temperatures. As shown by the equation, the output voltage may be controlled by adjusting the ratio of R1 600 and R2 612. Further, the regulator output voltage may not be susceptible to variations in the supply voltage at the supply voltage input 610. The regulator output may be utilized as a supply voltage for a clock buffer circuit.

FIG. 6B is a block diagram of an exemplary multistage clock buffer circuit for driving a capacitive load, in accordance with an embodiment of the invention. Referring FIG. 6B, there are shown three clock driver stages 603, 604, and 605. Referring to the first clock driver stage 603, there are shown transistors Q1 607 and Q2 608, resistor R1 609, and capacitor C1 606. Q1 607 may be a PMOS transistor and Q2 608 may be an NMOS transistor. The source of Q1 607 may be coupled to a power supply node, which may correspond to the regulator output 611 described above. The drains of Q1 607 and Q2 608 may be coupled together and may also be coupled to a first end of R1. A second end of R1 609 may be coupled to the gates of the transistors Q1 607 and Q2 608 as well as a first end of C1 606.

In operation, the circuitry shown in the first clock driver stage 603 may be capable of amplifying a clock signal that may be input into a second end of the capacitor C1 606. The amount of gain may be related to the gate bias voltage of the transistors. In this regard, it may be shown that the gate bias voltages are equal to half the regulator output voltage 611. Thus, a variation in the supply voltage may be utilized to change the gain of the circuit. The capacitor C1 606 one may be utilized to prevent external DC voltages from interfering with the gate bias voltages while at the same time may allow for the amplification of the AC portion of a clock signal.

The second and third clock driver stages 604 and 605 may comprise circuitry similar to that utilized in the first clock driver stage 603. These stages may be utilized to provide further amplification. The transistors in the second and third clock driver stages 604 and 605 may be larger in width and therefore may be capable of driving larger capacitive loads than the first clock driver stage 603. The combination of the voltage regulator circuit in FIG. 6A and the multistage clock driver circuit of FIG. 6B may therefore enable the stable amplification of a clock signal and the driving of a relatively large capacitive load in the presence of supply voltage variations. It should be understood that the number of stages shown is only exemplary and that more or less stages may be utilized depending on factors such as the amount of gain required, the size of the load, and the types of transistors.

Another embodiment of the invention may provide a method for performing the steps as described herein for buffering a clock signal is provided. For example, the system shown in FIG. 4 may be configured to self-bias a PMOS transistor 402 of the buffer shown, and may also be configured to bias an NMOS transistor 403 of the buffer via a controllable current source 400 to produce a second bias voltage at the gate of the NMOS transistor 403. The gain of the buffer may be controlled by varying a controllable current source 400 coupled to a second NMOS transistor 401 configured as a diode. Two coupling capacitors 406 and 407 may be utilized to remove a DC component of the signal. Multiple buffers 500, 501, and 502 (FIG. 5) may be coupled end-to-end to increase the overall drive capability, where the channel width of the transistors within the transistors may be doubled in each successive buffer. The clock signal may correspond to an in-phase or quadrature phase signal.

Accordingly, the present invention may be realized in hardware, software, or a combination of hardware and software. The present invention may be realized in a centralized fashion in at least one computer system, or in a distributed fashion where different elements are spread across several interconnected computer systems. Any kind of computer system or other apparatus adapted for carrying out the methods described herein is suited. A typical combination of hardware and software may be a general-purpose computer system with a computer program that, when being loaded and executed, controls the computer system such that it carries out the methods described herein.

The present invention may also be embedded in a computer program product, which comprises all the features enabling the implementation of the methods described herein, and which when loaded in a computer system is able to carry out these methods. Computer program in the present context means any expression, in any language, code or notation, of a set of instructions intended to cause a system having an information processing capability to perform a particular function either directly or after either or both of the following: a) conversion to another language, code or notation; b) reproduction in a different material form.

While the present invention has been described with reference to certain embodiments, it will be understood by those skilled in the art that various changes may be made and equivalents may be substituted without departing from the scope of the present invention. In addition, many modifications may be made to adapt a particular situation or material to the teachings of the present invention without departing from its scope. Therefore, it is intended that the present invention not be limited to the particular embodiment disclosed, but that the present invention will include all embodiments falling within the scope of the appended claims.

1. A method for processing signals in a communication system, the method comprising:
self-biasing a first transistor of a buffer for amplifying a clock signal to produce a first bias voltage at a gate of said first transistor; and
biasing a second transistor of said buffer via a controllable current source to produce a second bias voltage at a gate of said second transistor.

2. The method according to claim 1 comprising, adjusting the gain of said buffer by varying a current supplied by said controllable current source.

3. The method according to claim 2, wherein said current supplied by said controllable current source passes through an NMOS transistor to produce said bias voltage for said second transistor.

4. The method according to claim 3, wherein a gate and source of said NMOS transistor are coupled together.

5. The method according to claim 1 comprising, removing a DC component of said clock signal via at least two coupling capacitors.

6. The method according to claim 1 comprising, coupling a plurality of said buffers end-to-end to increase a drive capability.

7. The method according to claim 6, wherein a width of said first and second transistors within said buffer is doubled for each successive buffer.

8. The method according to claim 1, wherein said first transistor is a PMOS transistor and said second transistor is an NMOS transistor.

9. The method according to claim 1, wherein said clock signal corresponds to an in-phase component of a base band signal.

10. The method according to claim 1, wherein said clock signal corresponds to a quadrature-phase component of a base band signal.

11. A system for processing signals in a communication system, the system comprising:
one or more circuits that enables self-biasing a first transistor of a buffer for amplifying a clock signal to produce a first bias voltage at a gate of said first transistor; and
said one or more circuits enables biasing a second transistor of said buffer via a controllable current source to produce a second bias voltage at a gate of said second transistor.

12. The system according to claim 11, wherein said one or more circuits enables adjusting the gain of said buffer by varying a current supplied by said controllable current source.

13. The system according to claim 12, wherein said current supplied by said controllable current source passes through an NMOS transistor to produce said bias voltage for said second transistor.

14. The system according to claim 13, wherein a gate and source of said NMOS transistor are coupled together.

15. The system according to claim 11, wherein said one or more circuits enables removing a DC component of said clock signal via at least two coupling capacitors.

16. The system according to claim 11, wherein said one or more circuits enables coupling a plurality of said buffers end-to-end to increase a drive capability.

17. The system according to claim 16, wherein a width of said first and second transistors within said buffer is doubled for each successive buffer.

18. The system according to claim 11, wherein said first transistor is a PMOS transistor and said second transistor is an NMOS transistor.

19. The system according to claim 11, wherein said clock signal corresponds to an in-phase component of a base band signal.

20. The system according to claim 11, wherein said clock signal corresponds to a quadrature-phase component of a base band signal.

21-30. (canceled)
